(19) United States
(12) Patent Application Publication
(10) Pub. No.: US 2009/0274321 A1
(43) Pub. Date: Nov. 5, 2009

(54) AUDIO AMPLIFIER AND TECHNIQUE FOR POWER EFFICIENCY THEREOF

(75) Inventor: Matthias Doppel, Weissenbrunn (DE)

Correspondence Address: BROOKS KUSHMAN P.C. / LEAR CORPORATION, 1000 TOWN CENTER, TWENTY-SECOND FLOOR, SOUTHFIELD, MI, 48075-1238, US

(73) Assignee: LEAR CORPORATION, Southfield, MI (US)

(21) Appl. No.: 12/112,210

(22) Filed: Apr. 30, 2008

(51) Int. Cl. H03G 3/00

(52) U.S. Cl. 381/104

(57) ABSTRACT

Some embodiments take the form of a vehicle audio amplifier comprising a plurality of amplifier stages and a controller. The amplifier stages are operatively coupled to each other and the amplifier stages include an input stage for receiving an audio signal and an output stage for driving at least one load in response to a supply voltage level. The controller is operatively coupled to the amplifier stages and configured to receive a volume signal that is indicative of a desired volume setting selected by a user. The controller is further configured to adjust the supply voltage level to the output stage to a first voltage level if the volume signal is less than a predetermined volume level. The controller is further configured to adjust the supply voltage level to the output stage to a second voltage level if the volume signal is greater than the predetermined volume level.

### BACKGROUND

1. Field

Embodiments of the present invention relate to audio amplifiers and more particularly to multi-stage audio amplifiers in a vehicle.

2. Background Art

Audio amplifiers exist in a variety of classes, such as class-A, class A-B, and class-D. Such amplifiers usually have an output stage, and possibly other stages, composed of electrical components that require electrical power to provide amplification functionality. The output stage may be conventionally powered with a relatively constant voltage level, regardless of power consumption requirements at the output stage. In this scenario, the output stage may be powered at a relatively constant level even at a lower volume, in which the amplifier requires less power relative to a higher volume. Such a condition may lead to the amplifier having reduced power efficiency.

### SUMMARY

Several embodiments of the present invention take the form of a vehicle audio amplifier, which has multiple amplifier stages and a controller. The amplifier stages include an input stage for receiving an audio signal from an entertainment device and an output stage for driving at least one load in response to a supply voltage level—the stages are coupled to one another. The controller is operatively coupled to the amplifier stages and configured to receive a volume signal indicative of a desired volume setting selected by a user. The controller is further configured to adjust the supply voltage level to the output stage to a first voltage level if the volume signal is less than a predetermined volume level. The controller is also configured to adjust the supply voltage level to the output stage to a second voltage level if the volume signal is greater than the predetermined volume level. The second voltage level is greater than the first voltage level.

### BRIEF DESCRIPTION OF THE DRAWINGS

Embodiments of the present invention described herein are recited with particularity in the appended claims. However, other features will become more apparent, and the embodiments may be best understood by referring to the following detailed description in conjunction with the accompanying drawings, in which:

FIG. 1 illustrates a schematic view of an audio amplifier system according to an embodiment of the present invention;

FIG. 2 illustrates a schematic view of an audio-amplifier output stage according to an embodiment of the present invention;

FIG. 3 illustrates a graph depicting dissipated power versus output power in an audio amplifier;

FIG. 4 illustrates a flow diagram depicting a method for improving power efficiency in an audio amplifier according to an embodiment of the present invention;

FIG. 5 illustrates a graph depicting varying the power supplied by a pair of switches in the output stage according to an embodiment of the present invention; and

FIG. 6 illustrates a graph depicting an output audio signal with respect to a varied power supply according to an embodiment of the present invention.

### DETAILED DESCRIPTION OF AN EMBODIMENT

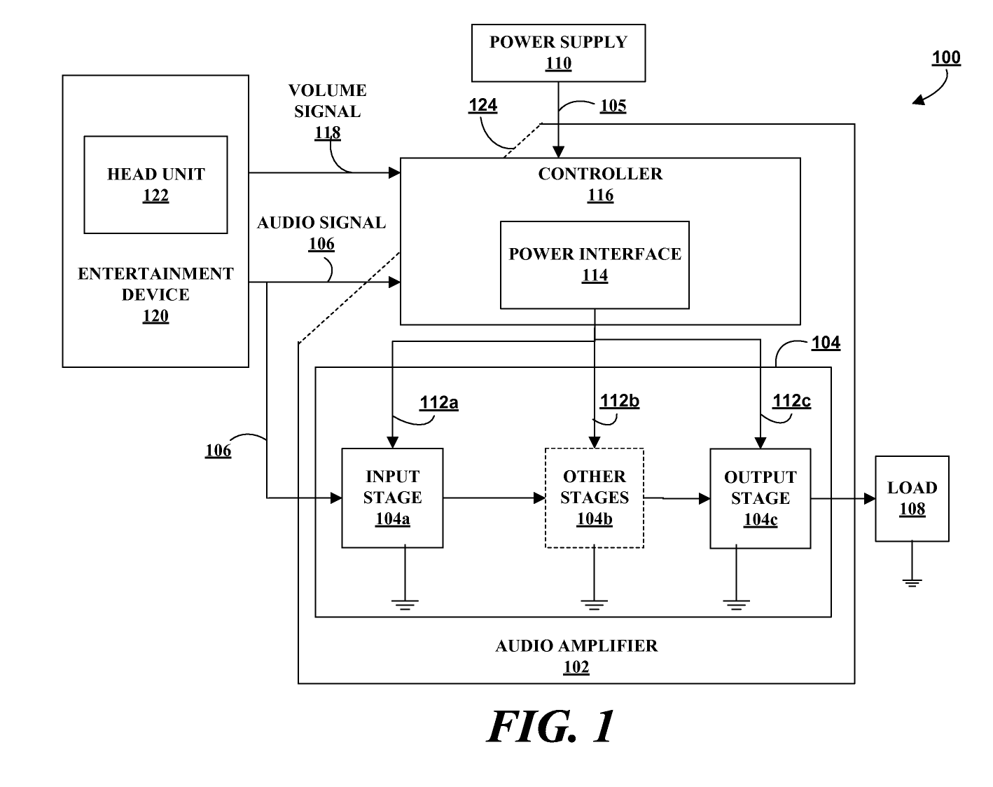

FIG. 1 shows a simplified schematic illustration of an audio amplifier system 100 according to an embodiment of the present invention. The audio amplifier system 100 includes an audio amplifier 102 that has multiple stages, which are generally designated as 104 and a controller 116. The amplifier 102 may be of any suitable multi-stage type, such as, for example, a class D amplifier. The amplifier 102 includes an input stage 104a and an output stage 104c. The audio amplifier 102 is configured to receive an audio signal 106 in order to amplify the audio signal (e.g., increase the audible level of the audio signal). The input stage 104a and the controller 116 are generally configured to receive the audio signal 106. At least one load 108 is coupled to the output stage 104c. The load 108 may include one or more speakers. As shown, the stages 104 are coupled in series, but may be suitably configured and coupled in a number of ways, for example, in a parallel configuration.

The amplifier stages 104 may include one or more additional stages 104b for performing a variety of suitable functions related to audio amplification. For example, the additional stages 104b may perform operations related to amplification, attenuation, filtering, wave-shaping, analog-to-digital (A/D) conversion, D/A conversion, impedance matching, or other such suitable operations. Notably, the choice and configuration of the components in the amplifier system 100 is not meant to be limiting and may vary based on the desired criterion of a particular implementation.

A power supply 110 provides power for the controller 116 as indicated by arrow 105. The power supply 110 may directly power the one or more stages 104a-104c but, practically, various components in the stages 104a-104c may necessitate a reduction of power, so as to not exceed the components' maximum supply voltage ratings (e.g., 5.0 volts). For this purpose, the controller 116 may include a power interface 114 (or power regulator) configured therein to regulate or control the amount of power delivered to the stages 104a-104c via signals 112a-112c, respectively. The input stages 104a and the additional stages 104b are configured to provide amplification functionality in response to the signals 112a and 112b, respectively. The output stage 104c is configured to drive the load 108 in response to the signal 112c. In general, the power supply 110 may be packaged within the amplifier 102 or separately from the amplifier 102.

Notably, the audio amplifier 100 is a linear system. Therefore, if the input voltage, along with the gains and attenuations of the amplifier stages 104 are determined, it is possible to calculate an output voltage of the output stage 104c.

While FIG. 1 illustrates that the power interface 114 is integrated within the controller 116, the system 100 contemplates that the power interface 114 may be separate from the controller 116. An entertainment device 120 is operably coupled to the controller 116. The entertainment device 120 transmits a volume signal 118 and the audio signal 106 to the controller 116. The volume signal 118 corresponds to a desired volume level selected by a user. The entertainment unit 120 may include any type of module generally situated in the vehicle to provide entertainment for the user with an audible signal. Such examples may include a radio having a compact disc player, DVD, and similar entertainment devices. The entertainment device 120 may provide other inputs such as, for example, inputs relating to audio amplification, power level, or inter-controller communication. The entertainment device 120 includes a head unit 122 having controls positioned thereon to allow the user to select the desired volume level.

In one example, the entertainment device 120 may be coupled to the controller 116 via a multiplexed communication bus. The multiplexed communication bus may be implemented as a control area network (CAN) bus or other such suitable multiplexed bus that is generally situated to transmit multiplexed communication messages therethrough. The volume signal 118 may be a multiplexed message transmitted by the entertainment device 120 where such a multiplexed message includes encoded data therein which corresponds to the desired volume level selected by the user. In yet another example, the entertainment device 120 may be hardwired coupled to the controller 116 such that the entertainment device 120 transmits an analog or digital signal as the volume signal 118 which is representative of desired amount of volume that is being requested by the user.

The controller 116 may be part of the audio amplifier 102, in that the audio amplifier packaging may include the controller 116. Alternatively, and as depicted by element 124, the controller 116 may be packaged separately from the audio amplifier 102 and operatively coupled therewith. In the latter scenario, the controller 116 may, for example, communicate with the power interface 114 and/or the stages 104a-104c via amplifier I/O ports (not shown). The controller 116 may include any suitable components such as, for example, one or more microprocessors, computer memory, analog discrete components, and the like to carry out the functionality of the controller, which is set forth in the following disclosure.

As mentioned, conventional multi-stage amplifiers may supply a relatively constant voltage level to an audio amplifier output stage, regardless of the amplifier's power consumption requirement at the output stage. This can lead to the amplifier having a reduced power efficiency when operating at lower volumes. Accordingly, in the system 100, a level associated with each of one or more inputs of the controller 116 is determined, and the supply voltage level (e.g., on the signal 112c) to the amplifier output stage 104c is varied based on the input level. One such input may be the volume signal 118. The supply voltage to the input stage 104a and the additional stages 104b may also be varied based on the input level, as dictated in part by the configuration of the amplifier.

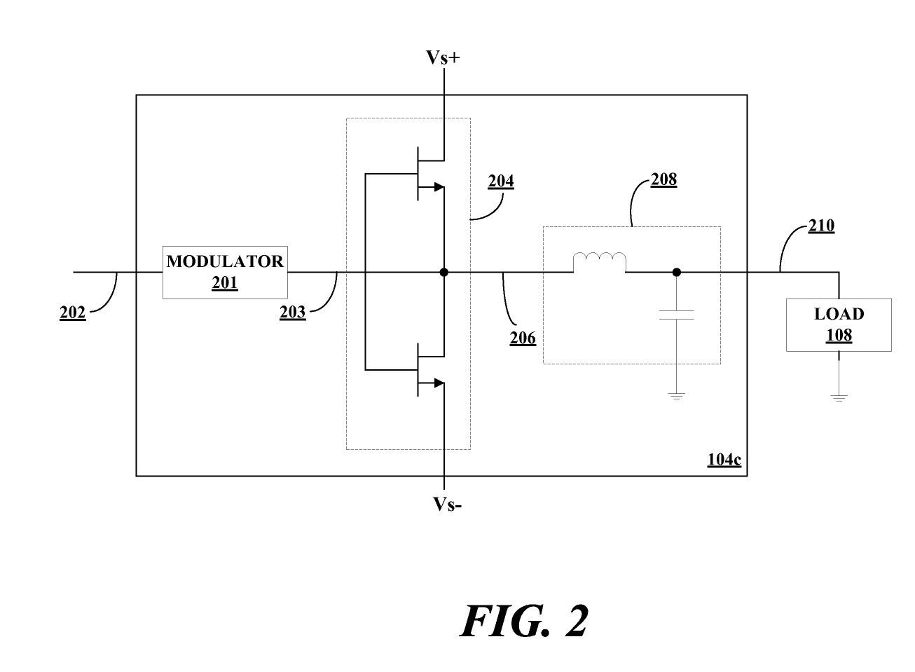

FIG. 2 shows a simplified schematic diagram of the amplifier output stage 104c according to an embodiment of the present invention. As shown, an audio signal is received at the modulator 201 along 202. The modulator 201 modulates the audio signal with a high-frequency carrier signal (e.g., 300 kHz fundamental frequency) and output the modulated signal along 203. The switches amplify this high frequency signal and output the amplified signal along 206. A filtering portion (generally 208) removes the carrier signal and passes select frequency components (e.g., 20 Hz-20 kHz) of the signal along 210 to the load 108. Notably, the duty cycle of the carrier signal is proportional to desired output voltage for the load. For example, a duty cycle of 50% would result in a voltage level approaching zero along 210.

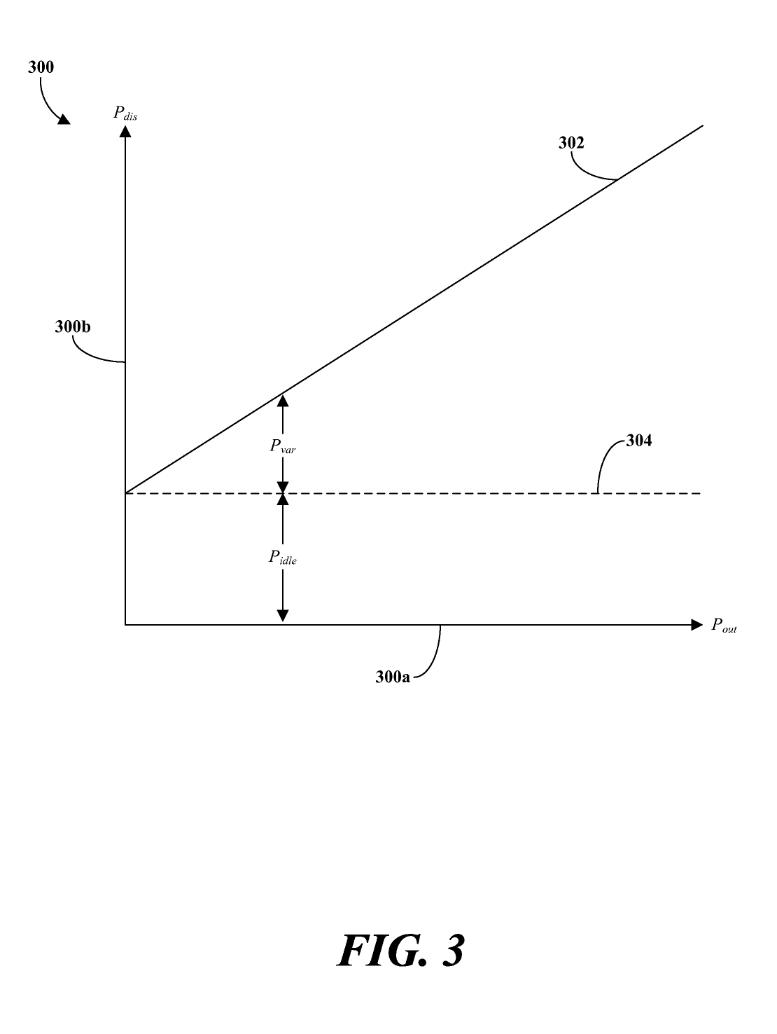

FIG. 3 shows a graph 300 illustrating total power dissipated in the audio amplifier 102 versus total output power generated by the amplifier 102. The horizontal axis 300a shows the output power; the vertical axis 300b shows the dissipated power. Accordingly, the curve 302 characterizes the total dissipated power in the audio amplifier 100 as a function of the total output power. The curve 302 has an idle power portion (P_{idle}) and a varying power portion (Pᵥₐᵣ); P_{idle} remains generally constant regardless of the output power, whereas Pᵥₐᵣ increases in a generally linear fashion with respect to output power. The idle power portion represents losses which may be independent from the output power, for example, quiescent currents, capacitive switching losses, magnetic switching losses, etc. The varying power portion may represent the resistive losses in the switching and filter circuitry in the various amplifier stages 104 (i.e., switches 204 and filter 208). Notably, at lower volumes (e.g., lower output power values), the idle power portion dominates the total power dissipation in the amplifier 102.

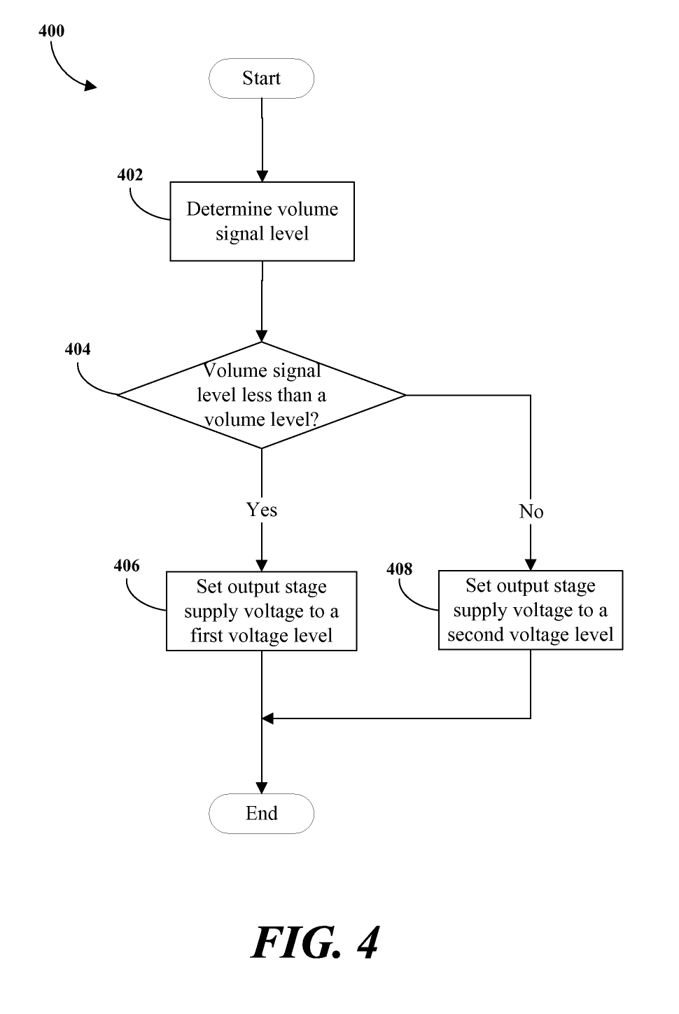

FIG. 4 shows a flow diagram 400 which illustrates a method for improving power efficiency in an audio amplifier, such as the amplifier 102, according to an embodiment of the present invention. The method may be carried out, for example, by the controller 116. Alternative configurations may be applied to the controller 116 for carrying out the method shown and described herein, such as a configuration of discrete analog components, comprising comparators, zener diodes, and other such components.

In block 402, the controller 116 determines the level of the volume signal 118. As noted above, the volume signal 118 may be digital, in which case the level of the volume may be determined, for example, by comparing the digital data on the volume signal 116 to sequences in a lookup table. In the case the volume signal 118 is an analog volume signal, a level detector may be used to determine the level of the volume signal. Signal characteristics, such as power, amplitude, and frequency may be used to determine the volume signal level. In the event the volume signal 118 is implemented as a multiplexed message, the controller 116 may decode the encoded data therein and compare data to known data stored on a lookup table.

In block 404, the controller 116 compares the level of volume signal 118 to a predetermined level. If the level of the volume signal 118 is less than the predetermined level, the method proceeds to block 406. If the level of the volume signal 118 is greater than the predetermined level, the method proceeds to block 408.

In block 406, the controller 116 via the power interface 114 reduces the amount of voltage (e.g., power) to a first voltage level delivered to the output stage 104c via the signal 112c. Such a reduction of power (or voltage) that is delivered to the output stage 104c may be between 25%-60% of the total amount of voltage capable of being applied to the output stage 104c. In one example, the controller 116 may control the power interface 114 such that the power interface 114 delivers half the amount of voltage (e.g., a 75% reduction of idle power) to the output state 104c via the signal 112c. The audio amplifier 102 may be operating in a power save mode by driving the output stage 104c at the first voltage level to reduce current consumption. It may not be efficient to drive the output stage 104c at an increased power level since the user may not require the volume of the audio signal 106 to be at a high level.

In block 408, the controller 116 via the power interface 114 increases the amount of voltage delivered to the output stage 104 via the signal 112. For example, the controller 116 may control the power interface 114 such that the power interface 116 delivers increased voltage levels to the output stage 104c to satisfy the user's request for increased volume levels as indicated on the volume signal 118. In such a case, a second voltage level may correspond to the increased voltage levels. In block 408, the audio amplifier 102 may be operating in a BOOST mode to meet the user's demand for increased volume levels of the audio signal 106.

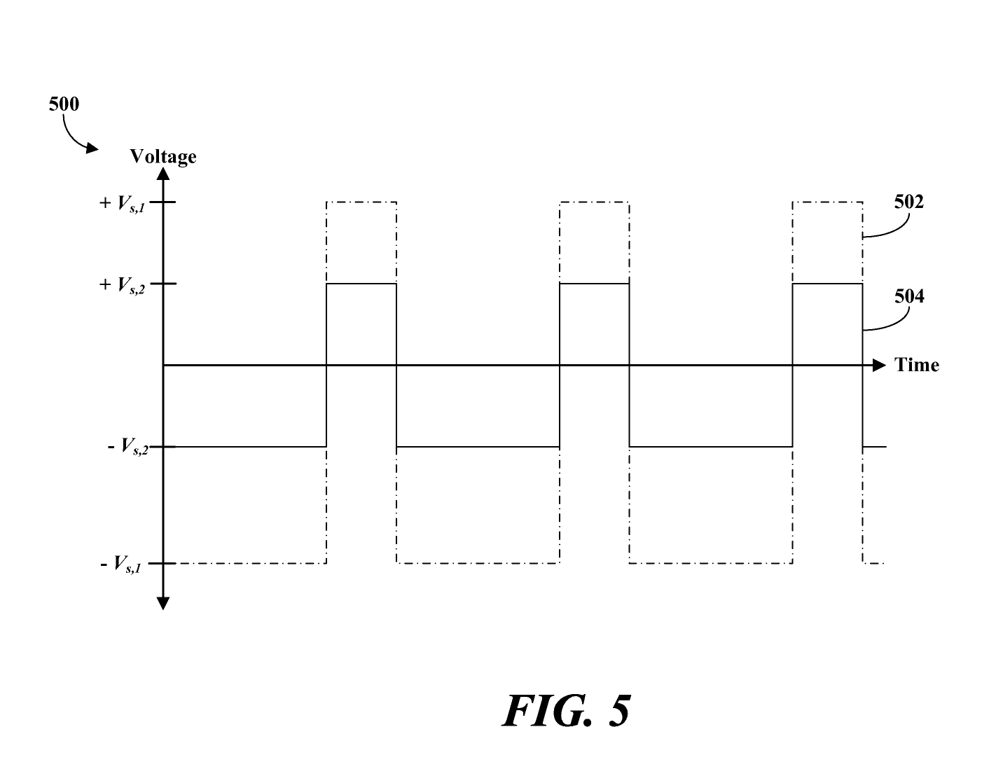

FIG. 5 shows an exemplary voltage versus time graph 500 that serves to illustrate this concept. The waveforms shown in the graph 500 may be those along line 206 of the output stage 104c (e.g., the audio signal modulated with the high-frequency carrier signal). If the level of the volume signal 118 is greater than the predetermined level, the source voltage is varied to have a peak voltage value of V_{s,1}, as in the source voltage waveform 502. If the volume signal level is less than the predetermined level, the source voltage is varied to have a peak voltage value of V_{s,2}, as shown by source voltage waveform 504. Of course, the waveforms may be varied by a different multiplicative factor than shown. Notably, the source voltage may also be varied to audio amplifier stages 104 other than the output stage 104c.

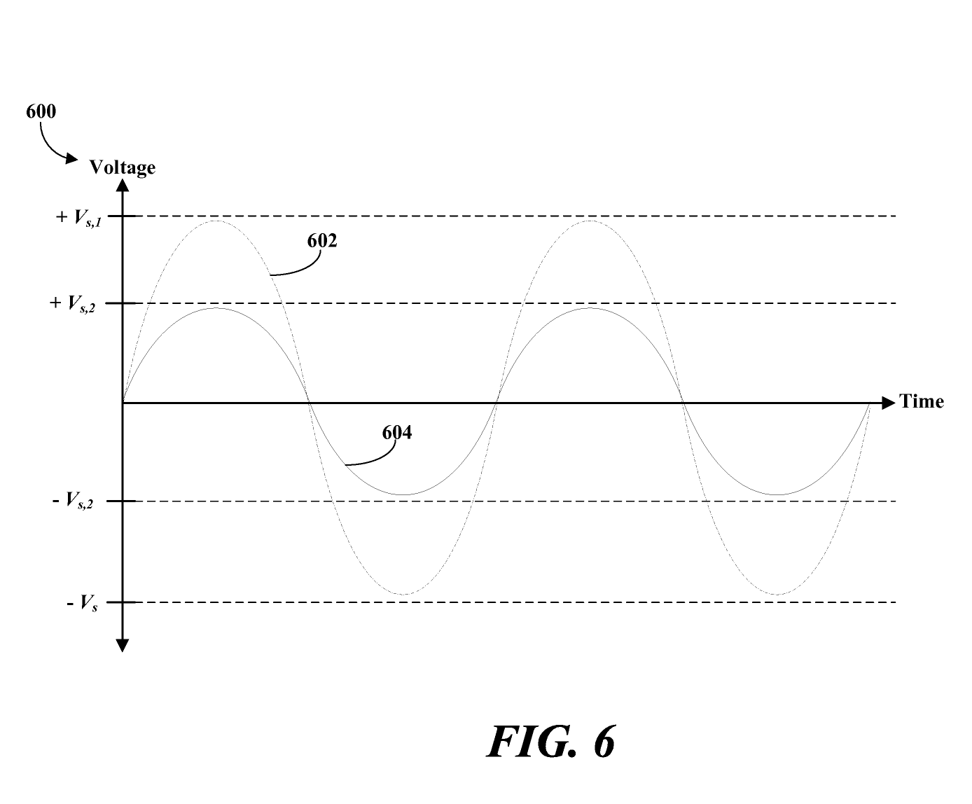

FIG. 6 shows a voltage versus time graph 600 of the audio signal along line 210. As mentioned, when the level of the volume signal 118 is greater than the predetermined level, the source voltage is varied to have a peak voltage value of V_{s,1} (waveform 502 in FIG. 5). Accordingly, the power level at this volume level would be sufficient to output an undistorted audio signal 602 to the load 108. As also mentioned, when the level of the volume signal 118 is less than the predetermined level, the source voltage is varied to have a peak voltage value of V_{s,2} (waveform 504 in FIG. 5). This allows for a sufficient power level without incurring distortion of the lower-volume audio signal 604; at the same time, the idle portion of the total dissipated power may be reduced at low volume levels, resulting in higher audio-amplifier power efficiency.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A vehicle audio amplifier comprising:
a plurality of amplifier stages operatively coupled to each other, wherein the amplifier stages include an input stage for receiving an audio signal from an entertainment device and an output stage for driving at least one load in response to a supply voltage level; and
a controller operatively coupled to the amplifier stages and configured to:
receive a volume signal from the entertainment device that is indicative of a desired volume setting selected by a user;
adjust the supply voltage level to the output stage to a first voltage level if the volume signal is less than a predetermined volume level; and
adjust the supply voltage level to the output stage to a second voltage level if the volume signal is greater than the predetermined volume level, wherein the second voltage level is greater than the first voltage level.

2. The audio amplifier of claim 1, wherein each amplifier stage is receptive to the supply voltage level, and the controller is configured to set the supply voltage level to the amplifier stages other than the output stage to the first voltage level if the volume signal is less than the predetermined level.

3. The audio amplifier of claim 1, wherein each amplifier stage is receptive to the supply voltage level, and the controller is configured to set the supply voltage level to the amplifier stages other than the output stage to the second voltage level if the volume signal is greater than the predetermined level.

4. The audio amplifier of claim 1, wherein the audio amplifier is a linear system.

5. The audio amplifier of claim 1, wherein the audio amplifier is a class-D audio amplifier.

6. The audio amplifier of claim 1, which further comprises a power interface apparatus operatively coupled to the output stage and configured to provide the supply voltage level thereto, wherein the power interface apparatus is further configured to receive a source voltage level from a power source external to the amplifier and adjust the source voltage level to the supply voltage level in response to the controller.

7. The audio amplifier of claim 1, wherein the output stage includes at least one device that operates at a minimum supply voltage for functionality, and wherein the first voltage level is greater than the minimum supply voltage of the device.

8. The audio amplifier of claim 1, wherein the supply voltage level is a time varying waveform.

9. The audio amplifier of claim 1, wherein the output stage has a modulator for modulating the audio signal and at least one switch for amplifying the modulated audio signal.

10. A vehicle audio amplifier system comprising:
an audio amplifier including a plurality of amplifier stages operatively coupled to each other, wherein the amplifier stages include an input stage for receiving an audio signal from an entertainment device and an output stage for driving at least one load in response to a supply voltage level; and
a controller operatively coupled to the audio amplifier and configured to:
receive multiple inputs including a volume signal from the entertainment device that is indicative of a desired volume setting selected by a user;
adjust the supply voltage level to the output stage to a first voltage level if a selected one of the inputs is less than a predetermined level; and
adjust the supply voltage level to the output stage to a second voltage level if the selected one of the inputs is greater than the predetermined level, wherein the second voltage level is greater than the first voltage level.

11. The audio amplifier system of claim 10, wherein each amplifier stage is receptive to the supply voltage level, and the controller is configured to adjust the supply voltage level to the amplifier stages other than the output stage to the first voltage level if the volume signal is less than the predetermined level.

12. The audio amplifier system of claim 10, wherein each amplifier stage is receptive to the supply voltage, and the controller is configured to adjust the supply voltage level to the amplifier stages other than the output stage to the second voltage level if the volume signal is greater than the predetermined level.

13. The audio amplifier system of claim 10, wherein the audio amplifier is a linear system.

14. The audio amplifier of claim 10, wherein the audio amplifier is a class-D audio amplifier.

15. The audio amplifier system of claim 10, further comprising a power supply configured to supply a source voltage level, wherein the audio amplifier includes a power interface operatively coupled with the audio amplifier stages and is configured to receive the source voltage level form the power supply, and wherein the power interface is configured to adjust the source voltage level to the supply voltage level in response to the controller.

16. The audio amplifier system of claim 10, wherein the audio amplifier output stage includes at least one device that operates a minimum supply voltage for functionality, and wherein the first voltage level is greater than the device's minimum required supply voltage.

17. The audio amplifier system of claim 10, wherein the supply voltage level has a time varying waveform.

18. The audio amplifier system of claim 10, wherein the output stage has a modulator for modulating the audio signal and at least one switch for amplifying the modulated audio signal.

19. The audio amplifier system of claim 10, further comprising an entertainment device configured to transmit the audio signal and the volume signal.

20. A method for controlling power consumption in a multi-stage audio amplifier of a vehicle, wherein the multi-stage audio amplifier includes an input stage for receiving an audio signal and an output stage for driving at least one load in response to a supply voltage level, the method comprising:
receiving a volume signal at the input stage from an entertainment device, wherein the volume signal is indicative of a desired volume setting selected by a user;
adjusting the supply voltage level to the output stage to a first voltage level if the volume signal is less than a predetermined level; and
adjusting the supply voltage level to the output stage to a second voltage level if the volume signal is greater than the predetermined level, wherein the second voltage level is greater than the first voltage level.
